(19) United States
(12) Patent Application Publication
(10) Pub. No.: US 2024/0246290 A1
(43) Pub. Date: Jul. 25, 2024

(54) 3D PRINTING USING RAPID TILTING OF A JET DEPOSITION NOZZLE

(71) Applicant: Optomec, Inc., Albuquerque, NM (US)

(72) Inventors: Michael J. Renn, New Richmond, WI (US); Kurt K. Christenson, Minnetonka, MN (US); Matthew Connor Schrandt, Stillwater, MN (US)

(73) Assignee: Optomec, Inc., Albuquerque, NM (US)

(21) Appl. No.: 18/561,461

(22) PCT Filed: May 16, 2022
(86) PCT No.: PCT/US2022/029435

§ 371 Date: Nov. 16, 2023

Related U.S. Application Data
(60) Provisional application No. 63/189,606, filed on May 17, 2021.

(51) Int. Cl. B29C 64/209; B29C 64/112; B29C 64/241; B29C 64/245; B29L 31/34; B33Y 10/00; B33Y 30/00; H05K 3/12

(52) U.S. Cl. CPC B29C 64/209; B29C 64/112; B29C 64/241; B29C 64/245; B33Y 10/00; B33Y 30/00; H05K 3/125; B29L 2031/3425

(57) ABSTRACT

Methods and apparatuses for printing a jet of ink, such as a jet produced by an aerosol jet apparatus or an ink jet printer. The print head is rapidly swiveled, tilted, pivoted, or rotated during deposition to print lines or other shapes on a substrate. Parallel lines and arbitrary shapes can be printed by shuttering the jet and/or moving the substrate relative to the print head. Metallic lines from the top surface to the bottom surface of the substrate can be wrapped around the edge of the substrate without losing electrical connectivity. In one example connections can be printed from a printed circuit board (PCB) to an integrated circuit on the PCB. The deposition rate can be over 50 mm/s, meaning that over 25 lines/s can be printed, depending on their length and thickness.

### CROSS-REFERENCE TO RELATED APPLICATIONS

This application claims priority to and the benefit of the filing of U.S. Provisional Patent Application No. 63/189,606, entitled “3D PRINTING USING RAPID TILTING OF AEROSOL JET NOZZLE”, filed on May 17, 2021, the entirety of which is incorporated herein by reference.

### BACKGROUND OF THE INVENTION

### Field of the Invention (Technical Field)

The present invention relates to the field of high-speed jet printing utilizing an angular tilting motion of a lightweight print head or nozzle to produce features and patterns on a substrate. The output mist from the nozzle is preferably collimated over several millimeters, which is preferably sufficient to print constant linewidth features over millimeter-sized steps, extended planar surfaces, or other topography.

### DESCRIPTION OF RELATED ART

Note that the following discussion may refer to a number of publications and references. Discussion of such publications herein is given for more complete background of the scientific principles and is not to be construed as an admission that such publications are prior art for patentability determination purposes.

### BRIEF SUMMARY OF THE INVENTION

Objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWINGS

The accompanying drawings, which are incorporated into and form a part of the specification, illustrate the practice of embodiments of the present invention and, together with the description, serve to explain the principles of the invention. The drawings are only for the purpose of illustrating certain embodiments of the invention and are not to be construed as limiting the invention. In the drawings:

FIG. 1 illustrates typical aerosol jet printing where the substrate moves beneath a stationary print head.

FIG. 2A is a depiction of a discrete print head attached to a rotary shaft.

FIG. 2B illustrates printing a line on the substrate by tilting a print head.

FIG. 2C is a depiction of multiple print heads attached to a rotary shaft.

FIG. 2D illustrates printing with multiple tilting print heads.

FIG. 2E illustrates printing on a curved surface.

FIGS. 3A-3B are schematics illustrating the progression of the pivoting motion of the deposition head/nozzle as it moves to print edge connections over the top side and edge of a substrate.

FIG. 4 is a schematic of a print path utilizing a jet for which printing can be interrupted by a shutter.

FIG. 5 is a schematic of a print path showing lines that are printed onto a more complex surface.

FIG. 6 is a schematic showing the titling of the print head coupled with a linear translation of the substrate in the X axis to print more complex patterns.

FIG. 7 is a schematic showing the substrate in continuous motion while the print head tilts.

FIG. 8 is a schematic showing the print head tilting about two axes.

FIG. 9 is a micrograph showing lines printed on the top and edge of a 1 mm thick glass slide at 25 lines/s.

FIG. 10A is a thickness map of the lines in FIG. 9.

FIG. 10B is a perspective thickness map of the lines in FIG. 9.

FIG. 10C is a line thickness profile of the 1 μm thick lines shown in FIG. 9.

FIG. 11A is a micrograph showing 10 mm long, 200 μm pitch lines printed using large angle tilt.

FIG. 11B is a higher magnification view of the lines of FIG. 11A near the edge of the sample.

FIG. 12 is a micrograph of silver lines on the top and edge of glass.

FIG. 13 is a micrograph of a two-point resistance measurement setup viewed from the top side of glass, also showing the edge of the glass.

### DETAILED DESCRIPTION OF THE INVENTION

In one or more embodiments of the present invention, one or more precision rotary motors are preferably used to produce rapid dynamic oscillation in the angular orientation of a light-weight print head or nozzle. Together with the linear or rotational translation of the substrate, this can be used to print features, for example small stroke features, onto a planar or non-planar surface. In one example, a continuous conductive trace can be created over the top surface, comer, and edge (sidewall) surface of a substrate. This connection from the top to the edge is often referred to as an “edge connection.” Connections from the top, across the edge, and around to the bottom surface of the substrate are often referred to as “wrap-around connections.” Flexible tubing preferably connects to the deposition head (e.g. ⅛″ OD plastic tubing) and provides push or carrier flows and sheath flows with negligible inertia. As used throughout the specification and claims, the term “jet” means any stream of ink that is propelled to a surface, including but not limited to an aerosol jet, such as a mist of liquid ink droplets (which may optionally contain solid material in suspension), fine solid particles, or mixtures thereof which are transported by a carrier gas, or a stream of drops that are ejected from, for example, a single-orifice jet dispenser or a multi-orifice ink-jet dispenser that are not entrained in a carrier gas. As used throughout the specification and claims, the term “print head” means print head, head, nozzle, deposition nozzle, syringe, dispense head, and the like, from which ink or another material is ejected. As used throughout the specification and claims, the term “moving the substrate and the print head relative to one another” or similar language means moving either or both of the substrate and the print head in one or more linear and/or angular (rotational) direction(s) or combinations thereof. As used throughout the specification and claims, the term “feature” means feature, line, figure, shape, and the like.

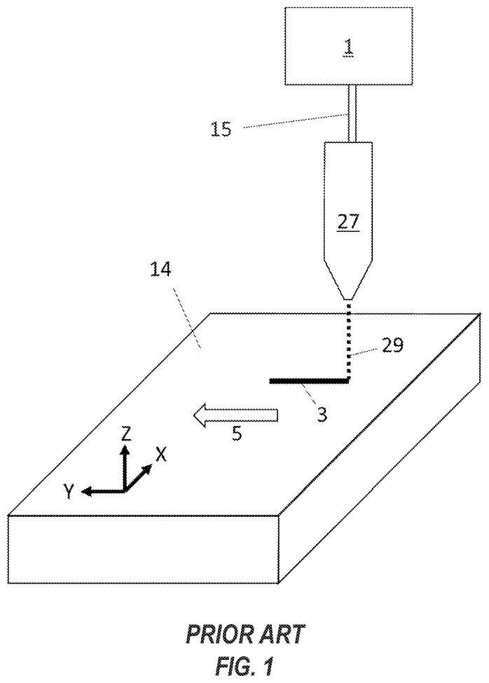

FIG. 1 shows a typical aerosol jet printing configuration where mist generator 1 atomizes an ink and supplies the mist through tube 15 to print head 27 that focuses the mist into a narrow jet 29 that impacts substrate 14. Line of ink 3 is drawn as substrate 14 moves in direction 5 relative to print head 27. In some automation configurations the print head is moved linearly in one or more axes and can be oriented at a fixed angle to the substrate. The angle of incidence of the jet to the substrate is typically perpendicular and is preferably within 45 degrees of normal.

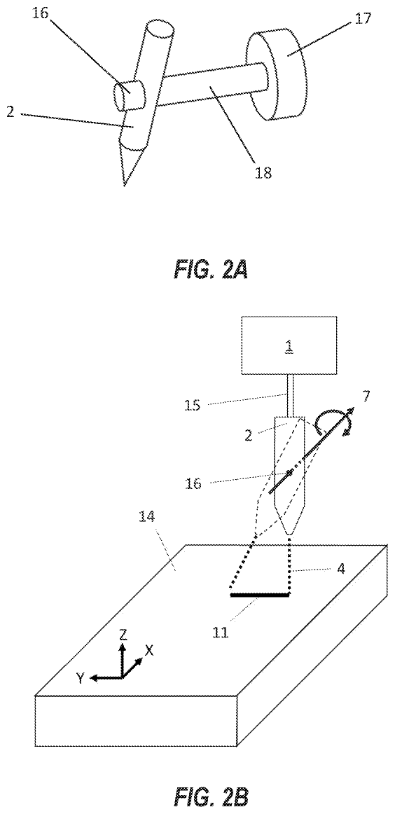

FIGS. 2A and 2B are variations of a first embodiment of the present invention. FIG. 2A shows print head 2 attached to shaft 18 via mount 16 so that print head 2 can be pivoted using rotary drive 17. Mount 16 is preferably configured so that jet 4 is ejected in a plane perpendicular to axis of rotation 7. However, it is anticipated that in some cases it will be advantageous for mount 16 to orient print head 2 non-perpendicular to axis of rotation 7 so that jet 4 sweeps out a cone during pivoting about axis of rotation 7. Any means of producing pivoting motion of print head 2, and preferably rapid oscillation, of print head 2 may be used. FIG. 2B shows mist generator 1 connected by tube 15 to print head 2, which pivots about axis of rotation 7, causing jet 4 to rapidly sweep across the substrate 14, thereby printing line 11. Print head 2 can be dynamically pivoted about one or more axes during printing, preferably around mount 16. As used throughout the specification and claims, the term “pivot” means rotate, oscillate, swivel, pivot, tilt, and the like. The angle of nozzle pivot is limited only by the limits of the rotational axis and can be variable between 0 and 360°. For example, pivoting of the nozzle can be used to print on the top of a substrate and then pivoted to print on the back side of the substrate. The range of nozzle pivots illustrated in the figures herein is shown as being less than 90° for clarity purposes only and is not to be construed as limiting the invention. FIGS. 2C-2D show an embodiment of the present invention comprising a plurality of print heads 52 printing multiple lines 54. Print heads 52 are attached to shaft 118 via mount 116 so that print heads 52 can be pivoted using rotary drive 117. Mount 116 is preferably configured so that the jets are ejected in a plane perpendicular to axis of rotation 67. However, it is anticipated that in some cases it will be advantageous for mount 116 to orient one or more of print head 52 non-perpendicular to axis of rotation 67 so that the corresponding jet(s) sweep out a cone during pivoting about axis of rotation 67. The print heads can pivot about a common axis of rotation 67 as shown, or each print head can pivot about a separate axis of rotation (not shown). The plurality of print heads of this embodiment can be used to multiplex, e.g. print parallel features simultaneously to increase effective throughput, or to raster by using each nozzle to print different features based on independent shuttering sequences.

As can be seen in FIG. 2B, the length of the printed line is limited by the variation in standoff as the head tilts. That is, when print head 2 is normal to a planar substrate, the standoff, i.e. the length of jet 4 or the distance from the tip of print head 2 to the planar substrate, is at a minimum. As the head pivots, the standoff distance from the tip to the substrate increases due to the arc traced by the tip of print head 2. There will typically be some maximum tilt angle, maximum jet length, and maximum line length beyond which the quality of the printed feature is unacceptable. FIG. 2E shows print head 2 printing on an internally curved surface 47. If surface 47 is circular and axis of rotation 7 is parallel and coaxial to the axis of curvature of the surface, as circumferential line 49 is printed, the standoff distance is constant regardless of tilt angle. The standoff distance would also be constant if the rotation axis was coaxial with an external surface and the head was dispensing on the external curved surface. Printing on curved surfaces may be beneficial, for instance in a roll-to-roll printing system.

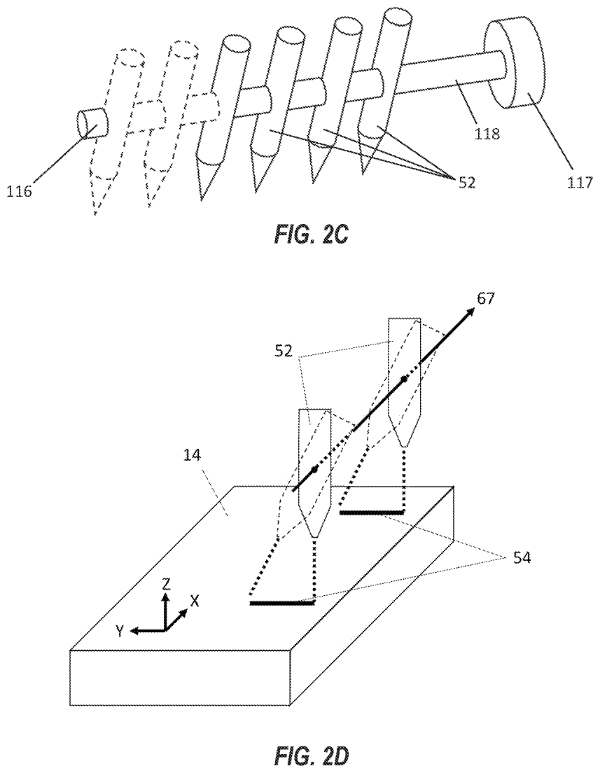

FIGS. 3A and 3B illustrate another embodiment of the present invention showing the progression of rapidly depositing the dispensed jet 4 along edge surface 10 and top surface 13 of substrate 14 to produce edge connections. The edge connections are printed by a shaft 6 pivoting about axis of rotation 7, which in this case is parallel to the X-axis of the substrate. The pivoting tilts print head 2, thereby translating the dispensed jet 4 to print each line 8 along the top surface 13 and side surface 10 of substrate 14, which in the pictured embodiment preferably remains stationary while printing of each line 8. Jet 4 sweeps through the YZ plane as the head is pivoted, causing the jet to traverse the surfaces of the substrate and print each line 8. In this embodiment a line is first printed in the +Z direction on side surface 10, then in the +Y direction on top surface 13, then the pivoting direction reverses to print over the deposited line in the −Y direction on top surface 13, and finally in the −Z direction on side surface 10. When the jet is aimed at positions 12 so that it is dispensing off substrate 14, substrate 14 is preferably stepped in the −X direction by the desired pitch of lines 8, and the next line is then printed. Either or both of print head 2 or substrate 14 can be stepped relative to one another to produce subsequent lines. This method of printing does not require interruption of the deposition of ink, termed shuttering, but it requires two passes for each line.

Wrapping printed lines around from the top surface, down the edge surface, and onto the bottom surface can be accomplished in a variety of ways including, but not limited to:
inverting the substrate (rotating about the Y axis) and repeating the printing process with the new lines on the side wall registered to the lines printed in the first pass:
rotating the substrate about the X axis to expose the bottom and side surfaces to the jet and repeating the printing process with appropriate pivoting of the print head; or
moving the substrate vertically (+Z) relative to the print head and pivoting the head to print on the side and bottom surfaces.

In other embodiments of the present invention, rapid shuttering is added to interrupt deposition of the jet in combination with the angular tilt of the nozzle and coordinated linear and/or angular translation of the substrate. Shuttering may include, but is not limited to, one or more of:
mechanical shuttering, for which the jet is physically blocked before or after leaving the print head;
external shuttering, for which the jet is pneumatically diverted after leaving the print head;
internal shuttering, for which the jet is pneumatically diverted before exiting the print head; or
pulse shuttering, for which the jet is briefly delayed within or before it reaches the print head.

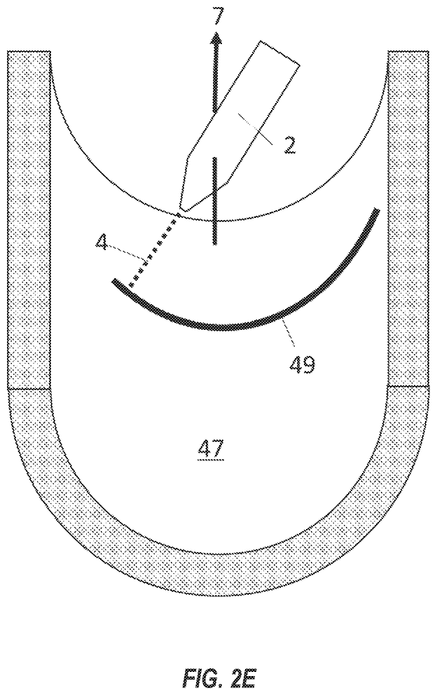

FIG. 4 illustrates jet 4 that is interrupted by an internal shutter (not shown) printing lines along the surfaces of a substrate 14. Edge connections are printed by rapidly tilting print head 2 connected to shaft 6 pivoting about axis of rotation 7. The pivoting turns the print head 2 in one direction and a line is printed from point 22 to point 24. The deposition is then interrupted by shuttering between printing passes while the substrate is moved in the −X direction by distance 28. Pivoting print head 2 in the opposite direction then prints from point 26 to point 30. The addition of rapid shuttering allows each line to be printed in a single pass instead of the two passes required by the shutter-free option illustrated in FIGS. 3A-3B.

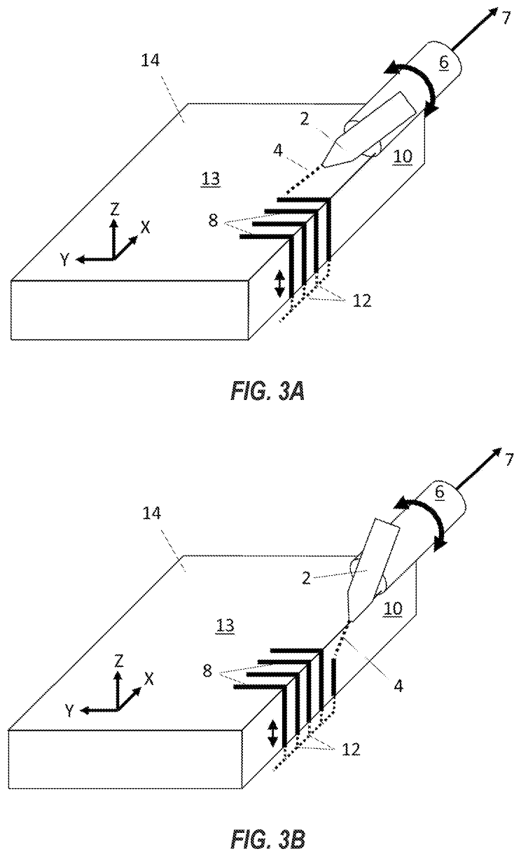

Lines can be drawn on planar or 3D substrates by combining rapid pivoting of the print head and linear motion of the substrate between prints. FIG. 5 shows an example of printing 3D lines from lower substrate 33 to upper substrate 31. Print head 2 prints jet 4 on horizontal surfaces 32 and 34 and vertical surface 40. If the limited range of printing in the Y direction provided by pivoting of the print head about axis of rotation 7 is sufficient, no Y-axis motion of the substrate is needed, significantly reducing automation costs. Alternatively, a lower cost Y stage may prove sufficient to translate the substrate between print locations. This print pattern could be used, for instance, to print electrical connections from a printed circuit board (PCB) up onto an integrated circuit (IC) die mounted on the board. A print speed of about 25 lines/s (90,000 lines/hr) compares favorably with the fastest current wire bond technology used to make connections to integrated circuits (70,000 connections/hr), and very favorably to typical wire bond rates of 30,000 connections/hr.

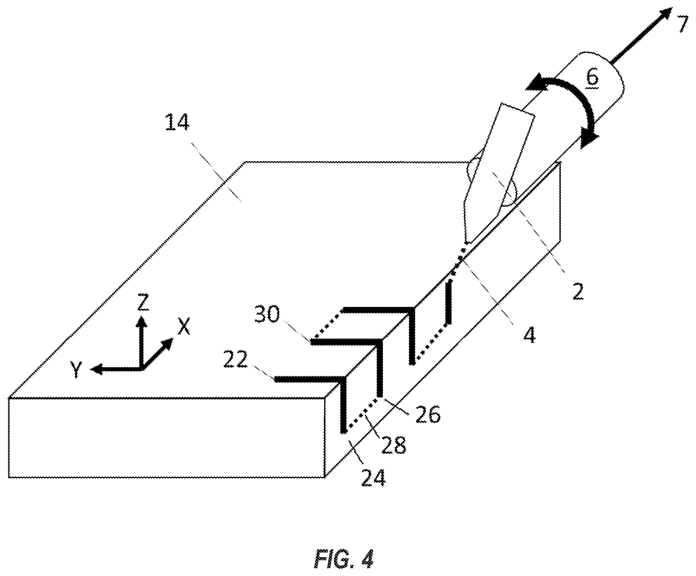

Lines of arbitrary shape can be drawn on planar or 3D substrates by combining pivoting of print head 2 with the translation of upper substrate 31 and lower substrate 33, as illustrated in FIG. 6. In one example, the substrates are moved in the X direction while line portions 42 on lower substrate 33 are printed. The combination of print head pivoting and moving the substrate and the print head relative to one another in one or more linear (X, Y, and/or Z) directions and/or through φ and θ angles allow for an arbitrary pattern to be printed on an arbitrarily shaped object.

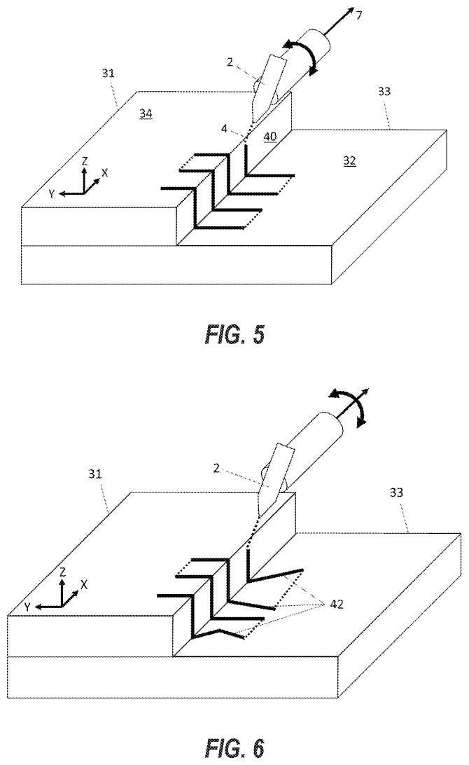

If the substrate is being moved, the motion of the substrate, particularly the acceleration of the substrate, is preferably minimized, especially when the substrate is heavy, unwieldly, fragile, and/or easily distorted. FIG. 7 illustrates substrate 14 in continuous motion in the −X direction 37. The direction of axis of rotation 8 and pivot velocity of print head 2 can be adjusted to match the motion in the X direction, printing a line parallel to the Y axis or other desired path.

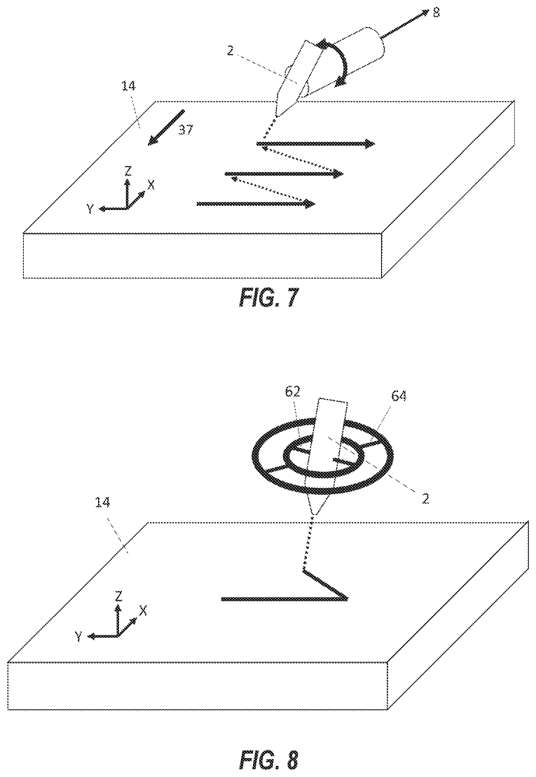

In another embodiment of the present invention, the print head is pivoted about two axes, providing the ability to print an arbitrary pattern over a limited area. FIG. 8 shows a dual gimbal with axes 62 and 64 controlling the orientation of print head 2. Coordinated pivoting of print head 2 around these axes allows the printing of arbitrary patterns on substrate 14. In another embodiment of the present invention, simultaneous rotation of the print head around three axes is used to bring the gimbal axes 62 and 64 into a more advantageous orientation for printing on a 3D part.

In all embodiments, the X, Y, Z, φ, and θ movement of the substrate and/or the print head relative to one another can be coordinated with one or more rotations of the print head when printing or when moving between print locations on a substrate. In some cases, rotating the print head about two or three axes will greatly increase the speed of the print process and/or eliminate the need for a high-performance stage(s) to move the substrate or printing assembly (i.e. the print head and/or mist supply apparatus). Alternatively, the same result can be achieved when the print head is rotated on one or more axes and linearly translated on one or more axes.

In another embodiment of the present invention, a motorized knuckle or universal joint is used to rotate the deposition head in one or more angular directions. The motorized knuckle replaces the motors that provide rotation around the rotational axes. A two-axis motorized knuckle would enable printing on all four edges of the substrate or printing the connections from a PCB up any edge (or up to all four edges) of an integrated circuit die, as shown in FIG. 5. The overall print rate of the line can exceed the linear translation of the substrate by a factor of 10 or more. Deposition rates above about 25 mm/s are preferably achieved using fast motors and/or low inertia print heads. High deposition rates are preferable when, for example, multiple passes are needed to build up the height of a narrow line or when depositing a thin coating on a large area with the jet focused to a small deposition spot. Narrow lines are preferably achieved with small tip outlet orifices and/or small standoff distances.

### EXAMPLES

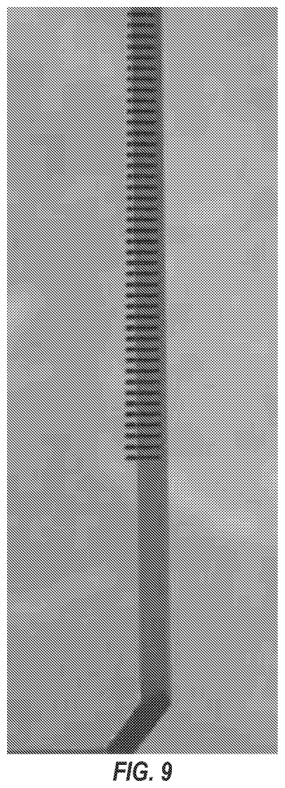

FIGS. 9-13 show results produced in accordance with the present invention, where a nanosilver ink was printed on the top and edge of the glass substrate.

### Example 1

In FIG. 9. 200 μm pitch, 100 μm wide lines were printed with an Optomec Sprint™ print head with a 300 μm nozzle or tip using 35 sccm push and 60 sccm sheath flows. The 1 mm long lines in FIG. 9 were printed at a rate of 25 lines/s with a linear velocity of the deposition greater than about 50 mm/s to allow for the back-and-forth motion and the linear motion of the substrate. The print head was pivoted approximately +/−10 degrees to print the millimeter length lines. The rotation axis was near the tip outlet of the print head with a tip to substrate spacing of 3 mm. (In other embodiments the angular pivot is preferably <10° when the rotation axis is above the tip outlet or the outlet to substrate distance is >3 mm.)

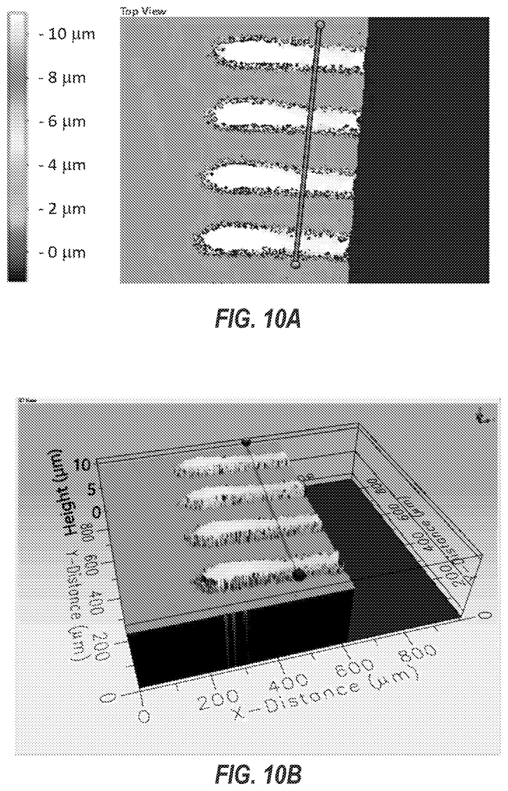

FIGS. 10A and 10B show two-dimensional thickness maps of the lines in FIG. 9, where the shading qualitatively indicates the local thickness of the deposit. The substrate registered a height of approximately 9.3 microns and the printed lines extended to a height of 10.3 microns, indicating an approximately 1 micron thick line. FIG. 10C shows a quantitative plot of the heights along the line shown in FIGS. 10A and 10B. The approximate 450 micron length of the lines is because the remainder of the 1 mm length is wrapped down the edge surface of the substrate.

### Example 2

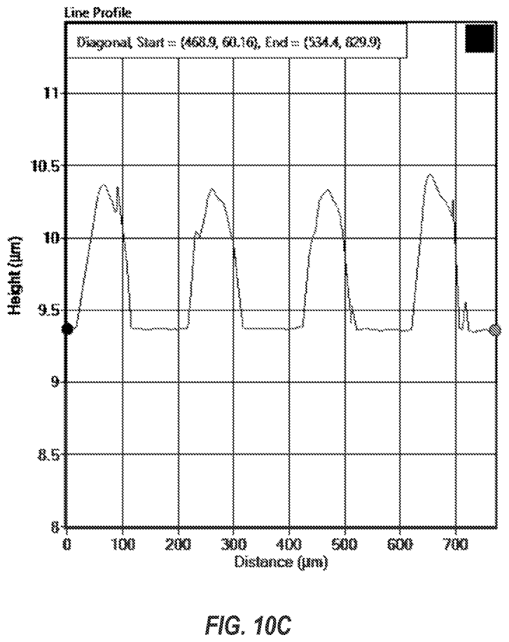

FIG. 11A shows lines greater than 10 mm in length created by tilting the head over a larger range than was used to produce the lines of Example 1. While the distance from the tip to the substrate varied with the tilt angle, the width of the line remained acceptably uniform. FIG. 11B shows a magnified image of the lines on the top and edge of the substrate.

### Example 3

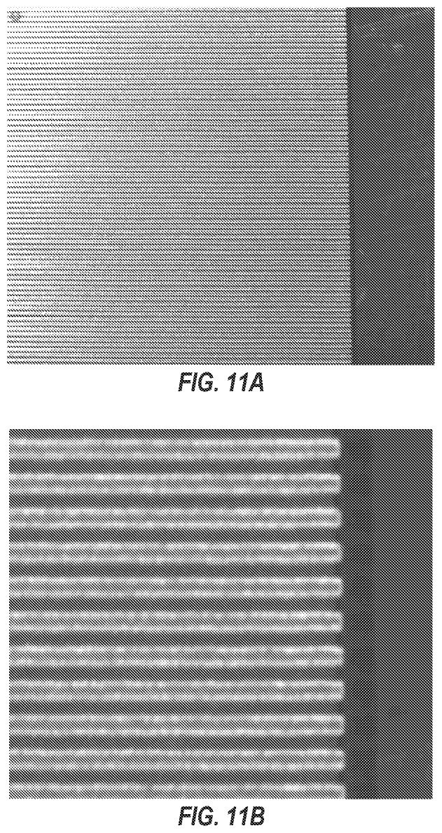

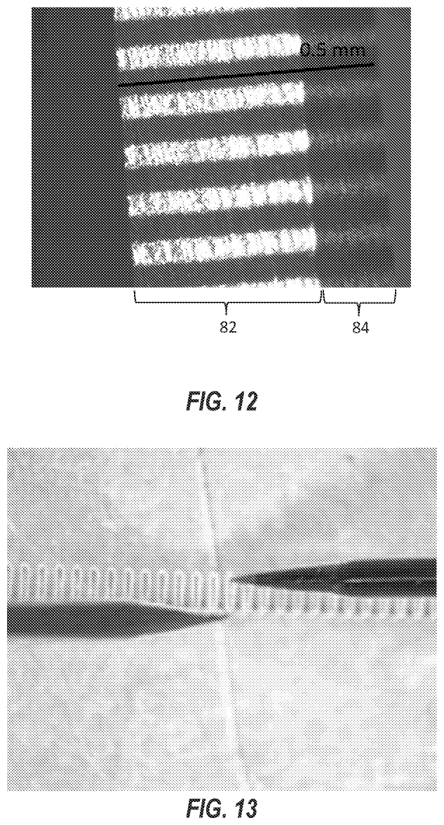

FIG. 12 and FIG. 13 show 1 mm long, 80 μm wide, 1 μm high silver lines on top surface 82 and edge surface 84 that were electrically continuous over the corner of the glass and had a resistance of 1.9 Ohms over the corner of the glass. FIG. 13 shows testing of the electrical continuity using a two-point probing from the top to the edge surface of the glass. The resistance can be reduced in a number of ways, for example by printing thicker lines, using a different ink formulation, varying the parameters used to sinter the ink, rounding the corners of the substrate, etc.

Note that in the specification and claims, “about” or “approximately” means within twenty percent (20%) of the numerical amount cited. As used herein, the singular forms “a.” “an,” and “the” include plural referents unless the context clearly dictates otherwise. Thus, for example, reference to “a functional group” refers to one or more functional groups, and reference to “the method” includes reference to equivalent steps and methods that would be understood and appreciated by those skilled in the art, and so forth.

Although the invention has been described in detail with particular reference to the disclosed embodiments, other embodiments can achieve the same results. Variations and modifications of the present invention will be obvious to those skilled in the art and it is intended to cover all such modifications and equivalents. The entire disclosures of all patents and publications cited above are hereby incorporated by reference.

1. A method of printing a feature comprising an ink, the method comprising pivoting a first print head during deposition of an aerosol jet or an ink jet comprising the ink, thereby printing a first feature on a first substrate.

2. The method of claim 1 wherein the first feature is in a plane defined by the first print head as it pivots.

3. The method of claim 1 wherein the first print head can be pivoted up to 180° in either pivot direction.

4. The method of claim 1 further comprising:
moving the first substrate and the first print head relative to one another; and
printing a second feature on the first substrate.

5. The method of claim 4 wherein the first feature is a first straight line and the second feature is a second straight line parallel to the first straight line.

6. The method of claim 4 wherein moving the first substrate and the first print head relative to one another is performed when the jet is not aimed at the first substrate.

7. The method of claim 6 comprising printing each feature in two passes so that the jet is not aimed at the first substrate at an end of the second pass.

8. The method of claim 4 comprising shuttering the jet prior to or while moving the first substrate and the first print head relative to one another.

9. The method of claim 8 wherein the first feature and the second feature are each printed in one pass.

10. The method of claim 1 wherein the first feature extends from a top surface of the first substrate to an edge surface of the first substrate.

11. The method of claim 10 wherein the first feature comprises an electrically conductive material and the line maintains electrically continuity around a corner of the first substrate between the top surface and the edge surface.

12. The method of claim 10 wherein the first feature further extends to a bottom surface of the first substrate.

13. The method of claim 12 wherein the first feature comprises an electrically conductive material and the first feature maintains electrically continuity around a corner of the first substrate between the edge surface and the bottom surface.

14. The method of claim 1 wherein the first feature extends from a top surface of the first substrate to an edge surface of a second substrate disposed on the first substrate.

15. The method of claim 14 wherein the first feature further extends to a top surface of the second substrate.

16. The method of claim 14 wherein the first substrate comprises a printed circuit board (PCB) and the second substrate comprises an integrated circuit (IC) die mounted on the PCB.

17. The method of claim 1 wherein printing the first feature does not require moving the first substrate and the first print head relative to one another other than pivoting the first print head.

18. The method of claim 1 further comprising pivoting the first print head about a second axis of rotation.

19. The method of claim 18 wherein the second axis of rotation is perpendicular to the first axis of rotation.

20. The method of claim 18 wherein the first axis of rotation and the second axis of rotation are provided by a dual gimbal.

21. The method of claim 1 performed with a deposition rate of the jet greater than approximately 25 mm/s.

22. The method of claim 21 performed with a deposition rate of the jet greater than approximately 50 mm/s.

23. The method of claim 1 further comprising pivoting two or more print heads.

24. The method of claim 23 comprising independently pivoting the first print head and a second print head.

25. The method of claim 24 wherein independently pivoting the first print head and the second print head comprises pivoting the first print head and the second print head about different axes of rotation.

26. The method of claim 23 further comprising independently shuttering the first print head and the second print head.

27. The method of claim 1 wherein the first substrate is curved.

28. The method of claim 27 wherein a curvature of the first substrate is circular concave.

29. The method of claim 28 wherein when an axis of rotation of the first print head is parallel to and coaxial with an axis of curvature of the circular surface a standoff distance between the first print head and the circular surface is constant during pivoting of the first print head.

30. (canceled)

31. The method of claim 1 wherein the feature comprises an electrically conductive material and comprises an electrical edge connection, an electrical wrap-around connection, or an electrical three dimensional (3D) interconnect.

32. The method of claim 31 wherein the feature comprises a 3D interconnect between two objects, each such object selected from the group consisting of a chip, a printed circuit board (PCB), a component, and a microLED tile.

33. The method of claim 31 wherein the feature comprises a 180° wraparound interconnect for a display substrate.

34. The method of claim 33 wherein the substrate is a glass substrate or a flex substrate.
